(19) United States
(12) Patent Application Publication
(10) Pub. No.: US 2010/0214831 A1
(43) Pub. Date: Aug. 26, 2010

(54) Memory device, memory system having the same, and programming method of a memory cell

(76) Inventors: Ho-Jung Kim, Suwon-si (KR); Chul-Woo Park, Yongin-si (KR); Sang-Beom Kang, Hwaseong-si (KR); Hyun-Ho Choi, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/588,536

(22) Filed: Oct. 19, 2009

(30) Foreign Application Priority Data
Feb. 26, 2009 (KR) 10-2009-0016330

(51) Int. Cl. G11C 11/00; G11C 8/00; G11C 7/10; G11C 7/00

(52) U.S. Cl. 365/163; 365/230.03; 365/189.04; 365/191; 365/148

(57) ABSTRACT

A memory device includes an array of resistance change memory cells divided into a first memory block including a first selected memory cell of a first plurality of memory cells and a second memory block including a second selected memory cell of a second plurality of memory cells, and sensing and writing circuitry configured to simultaneously activate a line connected with the first and second selected memory cells. The first and second selected memory cells may be written by iteratively applying a level-controlled write signal to memory cells not having a programmed state equal to the write data until a verify-read operation indicates respective programmed states for the first and second selected memory cells are equal to the write data.

### 1. FIELD

Embodiments relate to a semiconductor device, and more particularly, to a semiconductor device which enables fast execution of a program speed, a semiconductor system having the same, and a method of programming a memory cell.

### 2. DESCRIPTION OF THE RELATED ART

Memories are divided into volatile memories and non-volatile memories. Dynamic random access memories (DRAMs) and static random access memories (SRAMs) are volatile memories, while and flash memories, resistive memories, and phase change memories are non-volatile memories. The resistive memory uses a resistance value of a memory device to store one or more bits of data.

An entire block of resistive memory cells cannot be programmed or erased simultaneously, as this would require too large a drive current. Accordingly, a block of such memory cells is programmed sequentially by applying a series of program pulses to respective cells. However, this results in a long programming time.

### SUMMARY

Embodiments are therefore directed to memory device, a system having the same, and a method of programming a memory cell, which substantially overcome one or more of the problems of the related art.

It is therefore a feature of an embodiment to provide a memory device that enables fast execution of a program speed, a semiconductor system having the same, and a method of programming a memory cell.

It is therefore another feature of an embodiment to provide a memory device that simultaneously activates more than one memory cell, a semiconductor system having the same, and a method of programming a memory cell.

It is yet another feature of an embodiment to provide a memory device that determines a pass/fail status on an individual cell basis, a semiconductor system having the same, and a method of programming a memory cell.

At least one of the above and other features and advantages may be realized by providing a memory device, including an array of resistance change memory cells divided into a first memory block including a first selected memory cell of a first plurality of memory cells and a second memory block including a second selected memory cell of a second plurality of memory cells, and sensing and writing circuitry configured to simultaneously activate a line connected with the first and second selected memory cells, to write the first and second selected memory cells with write data by applying a level-controlled write signal to the first and second selected memory cells, to perform a verify-read operation on the first and second selected memory cells, and, when at least one of the first and second selected memory cells has a programmed state that is not equal to the write data, to iteratively apply the level-controlled write signal to the at least one of the first and second selected memory cells not having a programmed state equal to the write data until the verify-read operation indicates respective programmed states for the first and second selected memory cells are equal to the write data.

To iteratively apply the level-controlled write signal, the sensing and writing circuitry may be configured to iteratively alter at least one of a magnitude, a width, and a slope of the level-controlled write signal. The sensing and writing circuitry may be configured to iteratively increase at least one of a magnitude, a width, and a slope of the level-controlled write signal.

In the memory device, a plurality of blocks may form a tile, adjacent tiles sharing sensing and writing circuitry.

The sensing and writing circuitry may be configured to iteratively apply the level-controlled write signal to a third selected memory cell of a third plurality of memory cells not having a programmed state equal to the write data. The third selected memory cell may be in a same block as one of the first and second memory blocks having a memory cell having a programmed state equal to the write data and the sensing and writing circuitry may be configured to simultaneously activate a line connected with the third selected memory cell and one of the first and second memory blocks having a memory cell not having a programmed state equal to the write data. The third selected memory cell may be in a different block than either one of the first and second memory blocks and the sensing and writing circuitry may be configured to simultaneously activate a line connected with the first to third selected memory cells. One of the first and second memory blocks may have a memory cell having a programmed state equal to the write data and the sensing and writing circuitry may be configured to simultaneously activate a line connected with the third selected memory cell and one of the first and second memory blocks having a memory cell not having a programmed state equal to the write data.

In each iteration, the sensing and writing circuitry may be configured to use an available voltage amount for each simultaneous activation of lines.

The resistance change memory cell may be a phase change memory cell. The phase change memory cell may include a diode.

The sensing and writing circuitry may be configured to verify read more memory cells simultaneously than were activated simultaneously.

The write data may be programmed as multi-level state in the memory cell.

At least one of the above and other features and advantages may be realized by providing a method of writing data in a phase change memory cell in a memory, the memory including N tiles, where N is greater than 2, the method including activating M memory cells, where M is greater than 2, in N tiles simultaneously, one memory cell within a tile be activated at a time, simultaneously supplying a write signal to the M memory cells in the N tiles, verify-reading the M memory cells in N tiles simultaneously, and when Q memory cells in N tiles pass, supplying the write signal to the M-Q memory cells in the N-Q tiles, wherein an amplitude of the write signal supplied to the M memory cells is less than the product of M and an amplitude of a single cell write signal.

Supplying the write signal may include sequentially programming each memory cell in individual ones of the N tiles. The memory may include partitions of P tiles. Each tile within a partition may have a selected memory cell. The partition may include two planes of P/2 tiles, the two planes being physically separated. Adjacent planes of different partitions may share a sensing and writing circuit.

In each iteration, supplying the write signal may use an available voltage amount for each simultaneous supplying of write signals. Supplying the write signal to the M-Q memory cells in the N-Q tiles may include altering at least one of a magnitude, a width, and a slope of the write signal.

At least one of the above and other features and advantages may be realized by providing a system, including a processor and a memory device. The memory device may include an array of resistance change memory cells divided into a first memory block including a first selected memory cell of a first plurality of memory cells and a second memory block including a second selected memory cell of a second plurality of memory cells, and sensing and writing circuitry configured to simultaneously activate a line connected with the first and second selected memory cells, to write the first and second selected memory cells with write data by applying a level-controlled write signal to the first and second selected memory cells, to perform a verify-read operation on the first and second selected memory cells, and, when at least one of the first and second selected memory cells has a programmed state that is not equal to the write data, to iteratively apply the level-controlled write signal to the at least one of the first and second selected memory cells not having a programmed state equal to the write data until the verify-read operation indicates respective programmed states for the first and second selected memory cells are equal to the write data.

### BRIEF DESCRIPTION OF THE DRAWINGS

The above and other features and advantages of will become more apparent to those of ordinary skill in the art by describing in detail exemplary embodiments with reference to the attached drawings, in which:

FIG. 1 illustrates a schematic view of a layout of a memory device;

FIG. 2 illustrates a schematic diagram of an exemplary block of the memory device;

FIG. 3 illustrates a flowchart of a method in accordance with an embodiment;

FIGS. 4A to 4C illustrate pulses for use in a programming method of FIG. 3 according to embodiments;

FIG. 5 illustrates a flowchart of a method in accordance with an embodiment;

FIG. 6 illustrates a block diagram of a memory system including a memory device in accordance with an embodiment;

FIG. 7 illustrates a block diagram of a memory device according to an embodiment;

FIG. 8 illustrates an input/output block for use with a particular memory cell in accordance with an embodiment;

FIG. 9 illustrates a block diagram of a portion of a memory device in accordance with an embodiment;

FIG. 10 illustrates an input/output block for use with a particular memory cell in accordance with an embodiment;

FIG. 11 illustrates a block diagram of a portion of a memory device in accordance with an embodiment;

FIG. 12 illustrates resistance distributions of different data states according to an embodiment;

FIG. 13 illustrates a timing diagram for reading a memory cell in accordance with an embodiment;

FIGS. 14 and 15 illustrate specific examples of resistive devices that may be used with embodiments; and

FIG. 16 illustrates a block diagram of a semiconductor system.

### DETAILED DESCRIPTION

Korean Patent Application No. 10-2009-0016330, filed on Feb. 26, 2009, in the Korean Intellectual Property Office, and entitled: “Resistive memory device, memory system including same, and programming method of the same,” is incorporated by reference herein in its entirety.

Exemplary embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Like reference numerals refer to like elements/features throughout the specification.

Hereinafter, embodiments of the invention will be described using a phase change random access memory device (PRAM) example. However, it will be apparent to those skilled in the art that embodiments may be applied to other forms of nonvolatile memory using resistance materials, such as a resistive RAM (RRAM), and a ferroelectric RAM (FRAM). Herein, the terms “write” and “program” are used interchangeably in this written description to denote operations for storing data in one or more memory cells.

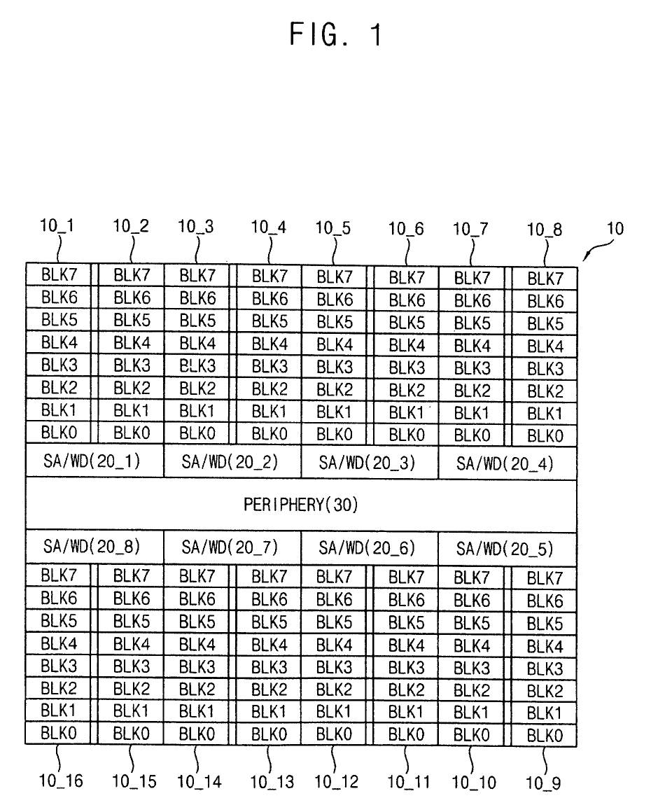

As illustrated in FIG. 1, a memory cell array 10 may include a plurality of memory banks, e.g., sixteen memory banks 10_1 to 10_16. Each bank 10_{—}i may include a plurality of blocks BLK0 to BLK7. Each block BLKj may include a plurality of bit lines BL0 to BLn and a plurality of word lines WL0 to WLm. A memory cell is located at the intersection of bit and word lines. A sense amplifier and write driver SA/WD 20_{—}i may be provided for a plurality of tiles or banks, i.e., all bit lines in a tile may be connected to a common SA/WD20_{—}i. In this particular example, each SA/WD 20_{—}i is connected to two banks, for a total eight SA/WD 20_1 to 20_8 in the memory cell array 10. The tiles may be grouped into planes, each plane including eight tiles. Two planes may form a partition. A peripheral circuit 30 may include logic to operate the SA/WD 20_{—}i and a voltage generator, as described in detail later.

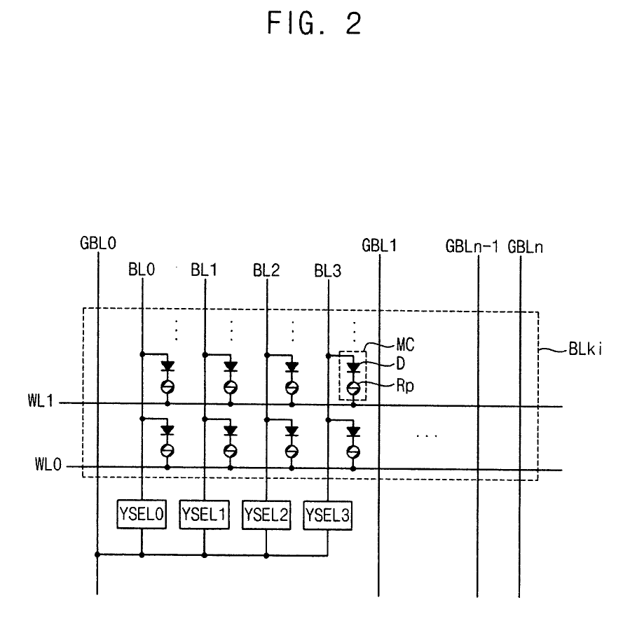

An example schematic of a block BLKi is illustrated in FIG. 2. As illustrated therein, each block BLKi may include a plurality of memory cells MC located at the intersection of a BL and a wordline WL. The memory cell MC may include a current control device D and a resistive element Rp. Each block BLKi may also include a plurality of global bitlines GBLi. In this particular example, each global bit line GBLi is associated with four bit lines BL0 to BL3. The global bitlines GBLi may control the bitlines associated therewith through corresponding transistors YSEL0 to YSEL3.

The word lines WLi may be responsive to a row address decoder (not shown) and the bit lines BLi may be selected responsive to a column address decoder (not shown). Such row and address decoders are well known in the art and need not be described further herein. As used herein, a word of data refers to the number of bits that are selected for a given output of the row address decoder and column address decoder (i.e. when a word line is active and a corresponding column select signal is active). Data may be sequentially applied to the SA/WD 20_{—}i, such that fewer than all of the write drivers for a word of data are simultaneously active, which may reduce the peak current requirements when the memory cells are programmed.

Each of the resistive elements Rp may be embodied by a phase change random access memory (PRAM). The PRAM, which may be referred to as a PCRAM or an ovonic unified memory (OUM), may use a phase change material, for example, chalcogenide alloy, for the resistive elements Rp. The phase change material may have a different resistance value according to a crystalline state, an amorphous state, or an intermediate state (when more than 1-bit data is to be programmed). For example, the phase change material may be a material of a compound of two elements, for example, GaSb, InSb, InSe, Sb₂Te₃, or GeTe, a material of a compound of three elements, for example, GeSbTe, GaSeTe, InSeTe, SnSb₂Te₄, or InSbGe, or a material of a compound of four elements, for example, AgInSbTe, (GnSn)SbTe, GeSb(SeTe), or Te₈₁Ge₁₅Sb₂S₂. Additional details regarding structures of the resistive elements according to embodiments will be discussed below.

The current control device D may be a diode or a transistor, e.g., a metal-oxide-semiconductor field effect transistor (MOSFET) or a bipolar junction transistor (BJT).

While conventional resistive memory devices can receive several bits of input at the same time, they are unable to simultaneously program the bits into corresponding memory cells. For example, a resistive memory device may receive 16 inputs through a plurality of pins, the memory device may not be able to simultaneously access 16 memory cells. One reason for this shortcoming is that if a current of 1 mA is required to program one memory cell, then a current of 16 mA would be required to simultaneously program 16 memory cells. Moreover, if the efficiency of a write driver providing the current is 10%, then in reality, a current of 160 mA would be required to simultaneously program the 16 memory cells. However, conventional memory devices are generally not equipped to provide currents with such high magnitudes.

Thus, since a write driver can only provide a limited amount of current, a program operation of several memory cells may be divided into several “divisional program operations” each requiring only a fraction of the total current required to program all of the several memory cells. In each divisional program operation, a subset (i.e., a “division”) of memory cells among a larger group is programmed. For example, a group of sixteen memory cells may be programmed by dividing the sixteen memory cells into eight groups (i.e., divisions) of two and simultaneously programming the two memory cells in each group of two in eight successive divisional program operations.

To prevent unnecessary current consumption and programming failures, the memory device may also perform a verify read operation to verify the program status of each selected memory cell. To perform the verify read operation, program data to be programmed in the selected memory cells may be stored in a temporary storage location, e.g., a program buffer. Next, the program data is programmed into selected cells. Then, the data stored in the selected memory cells may be read and compared with the program data stored in the temporary storage location. Where the data stored in the temporary storage location is different from the data stored in the selected memory cells, the verify read operation indicates a program failure. Otherwise, the verify read operation indicates a program success.

In the configuration illustrated in FIGS. 1 and 2, each block BLKi may have one selected cell selected simultaneously with cells in different block within the same bank. In other words, cells in the same block BLKi may be programmed sequentially from other memory cells in same block BLKi.

Conventionally, when memory cells are programmed simultaneously in a group, if one memory cell in that group has not been successfully programmed, then that group is considered a failed group. Then, that group is subject to another program loop. In other words, in each program loop, program data is programmed to selected cells using a plurality of divisional program operations corresponding to cell groups including the selected memory cells. However, in each program loop, divisional program operations are only performed on cell groups including selected memory cells that have not been successfully programmed, i.e., “failed groups”. A general discussion of such division programming is set forth, for example, in U.S. Pat. No. 7,535,747, which is hereby incorporated by reference in its entirety.

In accordance with embodiments, one memory cell in each tile may be programmed at a time and each tile may have a memory cell to be programmed for at least an initial programming period. Before or after each program loop, a verify read operation may be performed to determine whether selected memory cells have been successfully programmed. As used herein, data to be programmed in selected memory cells will be referred to as program data, and data read from the selected memory cells in a verify read operation will be referred to as verification data.

The greater the number of memory cells on a wordline that are simultaneously accessed, the greater the wordline current. In the particular example illustrated in FIGS. 1 and 2, each block BLKi in a bank or tile 10_{—}i may output one bit, for a total of sixteen bits per tile. In order to program a certain number of bits, e.g., 128 bits, eight tiles may be linked to output sixteen bits from each of the eight tiles. However, activation of the line connected with all target blocks may be simultaneous, since activation doesn't require much current, i.e., merely places the cell in a standby state ready for programming.

In accordance with embodiments, the pass/fail assessment may be performed on a individual memory cell basis. In other words, in a subsequent program loop, memory cells in different blocks that were previously programmed sequentially may be programmed simultaneously, to thereby reduce programming time. Alternatively, in a subsequent program loop, when a memory cell in a block has passed, another memory cell, connected to the same wordline, may be programmed simultaneously with failed memory cells in different blocks. Further, in accordance with embodiments, since verify read operation requires less current than programming operations, verify read operations may be performed on more memory cells simultaneously than were programmed. The simultaneous programming across program loops may consume a same amount of current, i.e., a bandwidth of each programming may be the same, thereby reducing an amount of time subsequent program loops may take.

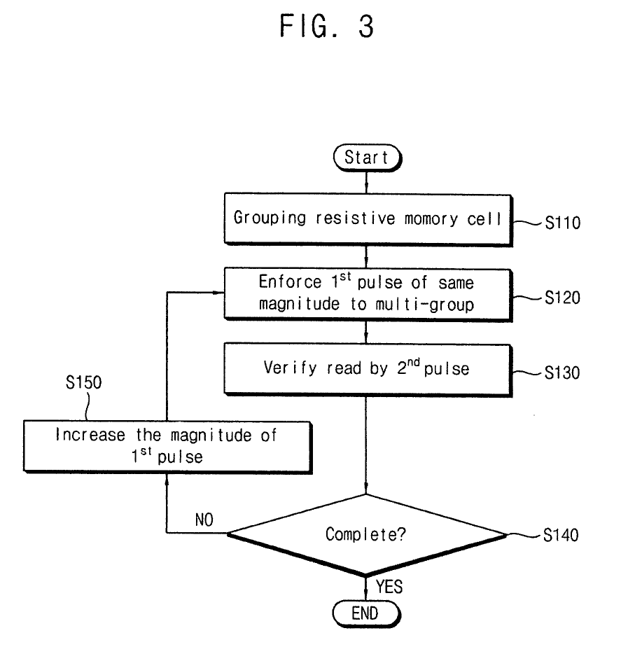

FIG. 3 illustrates a flowchart of a program method according to an embodiment. First, memory cells are grouped in operation S110 as discussed above, i.e., a single memory cell in each block BLKi is simultaneously activated for a predetermined number of blocks along a same wordline. Then, in operation S120, an identical program pulse may be applied to each group, i.e., each memory cell within a group simultaneously and to all memory cells within different groups sequentially. In operation S130, a verify read operation may be performed on all memory cells for the wordline by applying a read pulse. If all of the memory cells for the wordline are properly programmed, then operation S140 determines that the program method is complete. If not, at least one of a magnitude, a width, and a slope of the program pulse may be altered, e.g., increased, in operation S150, and a different program pulse may be applied to the failed memory cells in a subsequent iteration of operations S120 to S140.

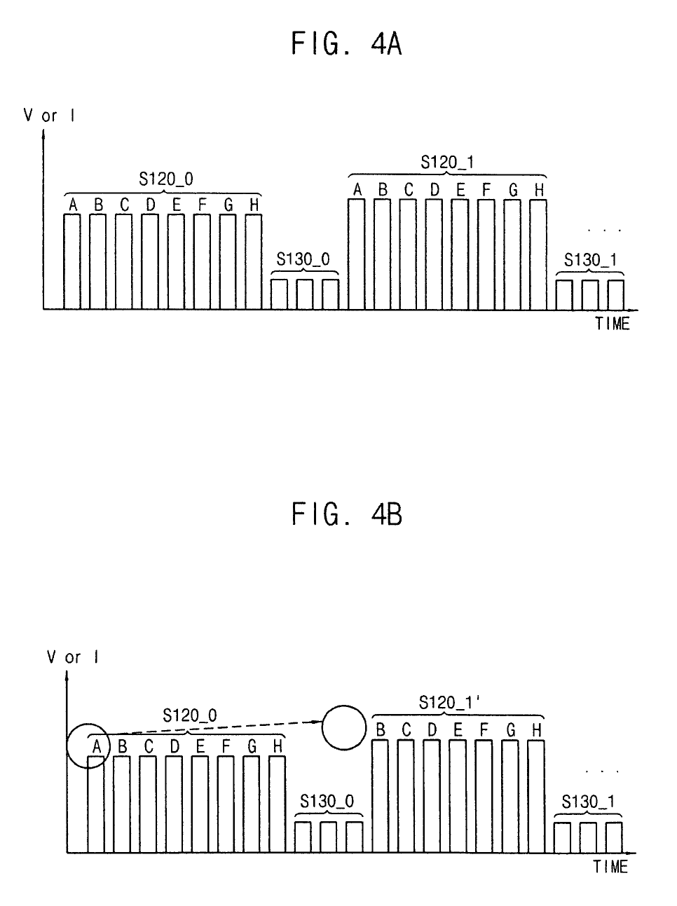

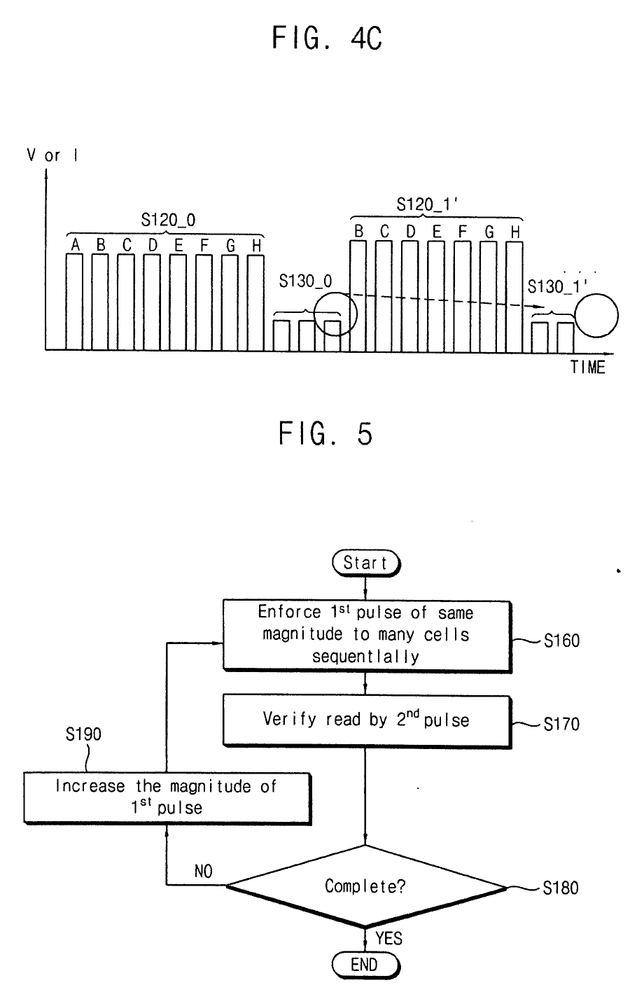

FIGS. 4A to 4C illustrate pulses for use with the program method illustrated in FIG. 3 according to different embodiments. A program pulse is typically applied either directly to a memory cell, or to a write driver generating a write current to program the memory cell. The term “program pulse” denotes an electrical current pulse causing a memory cell to become programmed, e.g., to assume the “set” or “reset” state. In particular, the term “reset pulse” denotes a program pulse causing a phase-change memory cell to assume the reset state, and the term “set pulse” denotes a program pulse causing a phase-change memory cell to assume the set state. In general, the duration and magnitude of the reset and set pulses are related to the duration and magnitude of corresponding temperature pulse characteristics of an associated memory cell.

As illustrated in FIG. 4A, according to an embodiment, a same program pulse may be applied to memory cells in the tiles simultaneously during operation S120_0 (the initial programming operation). Then, verify reading pulses may be applied to memory cells during operation S130_0 (the initial verify read operation). Since the verify read operation requires less current than the program operation, more memory cells may be activated simultaneously during the verify read operation, requiring fewer pulses and reduced time. Those memory cells that do not pass may be programmed again with a different program pulse during operation S120_1 (first iteration), and then verify read again during operation S130_1 (first iteration). This process may be repeated for successive iterations until all memory cells associated with that wordline are properly programmed.

As illustrated in FIG. 4B, again a same program pulse may be applied to memory cells in the tiles simultaneously during operation S120_0 and verify read pulses may be applied to memory cells during operation S130_0. However, before applying the different program pulse to the memory cells that have failed, blocks having memory cells that passed may be excluded in the next program loop, but a voltage required for simultaneous programming may be maintained across program loops, thereby requiring fewer pulses and reduced time in operation S120_1′ (first iteration). For example, a next or subsequent memory cell in a block having the passed memory cell may be simultaneously activated with other failed memory cells in other blocks and/or a next or subsequent block in a tile having a passed block may be simultaneously activated with other failed blocks in other tiles. In other words, the sequent of programming may be shifted such that simultaneous programming uses all current available as soon as possible. Subsequent iteration may further reduce the number of pulses and time as the number of properly programmed memory cells increases with subsequent iterations.

As illustrated in FIG. 4C, the same pulses as in FIG. 4B may be used until the read verify operation S130_1′ after the iterative program pulse application. In the second verify read operation S130_1′, when the number of memory cells to be programmed has been reduced, a number of memory cells to be read is also reduced, and these may be further grouped to reduce the number of read pulses.

FIG. 5 illustrates an alternative program method according to an embodiment. As shown therein, rather than grouping the memory cells, each cell is programmed sequentially during operation S160. Then, the verify read operation may be performed in operation S170. If operation S180 determines all of the memory cells for the wordline are properly programmed, then the program method is complete. If not, operation S190 may alter, e.g., increase, at least one of a magnitude, a width, and a slope of the program pulse applied to the failed memory cells in a subsequent iteration of operations S160 to S180. In particular, timing of programming of each failed memory cell may be moved up to timing of programming of a passed memory cell.

While the above program methods have illustrated a continuous write method, i.e., all memory cells for the wordline are programmed before verify read operation is performed, the above program methods may be adapted to employ a suspend write method, as set forth, for example, in U.S. Pat. No. 7,535,747 or a suspend program method, as set forth, for example, in U.S. Patent Application No. 2008/0056023, both of which are hereby incorporated by reference in their entirety.

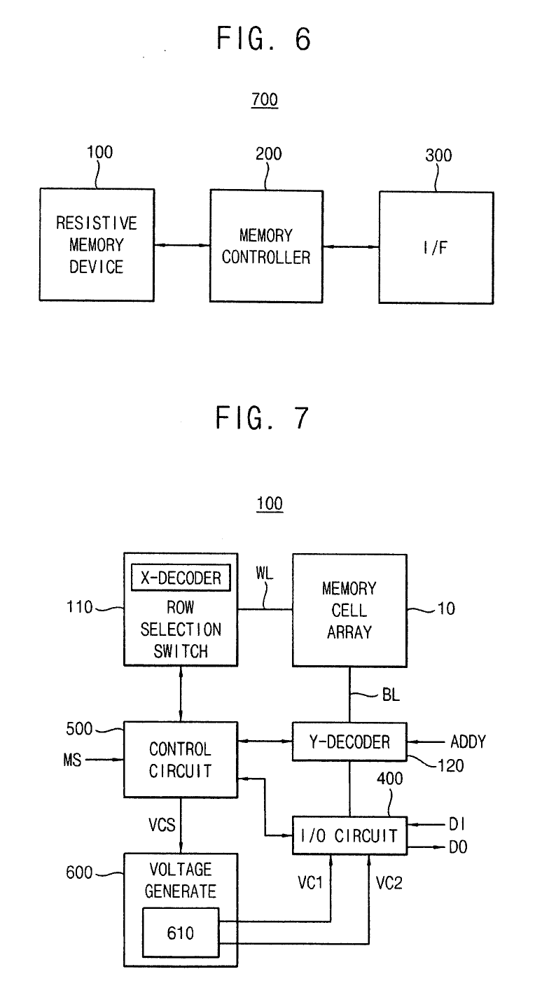

FIG. 6 illustrates a block diagram of an exemplary memory system 700 according to embodiments. As illustrated therein, the memory system 700 may include a resistive memory device 100, a memory controller 200, and an interface 300.

A detailed block diagram of the resistive memory device 100 is illustrated in FIG. 7. As shown therein, the resistive memory device 100 may include the memory cell array 10, a row selection block 110, a column decoder 120, an input/output (I/O) block 400, a control block 500, and a voltage generator 600. While FIG. 7 only shows a single wordline WL and bitline BL for ease of illustration, it is to be understood that respective memory cells within the memory cell array 10 are at an intersection of a corresponding plurality of wordlines and bitlines, and are selected in accordance therewith.

The row selection block 110 may include a row decoder configured to select a wordline WL in accordance with a row address ADDX for read or write operations. The row selection block 110 may also include a driver to insure a particular voltage for selected and unselected wordlines, respectively.

The column decoder 120 may be configured to select a bitline BL in accordance with a column address ADDY for read or write operations in accordance. Data to be read from or written to respective memory cells may be controlled by the I/O block 400, described in detail below.

The control block 500 may respond to a mode signal MS and may control operation of the I/O block 400. The mode signal MS may be supplied from outside or may be supplied internally by the control block 500 itself in accordance with an address signal ADDX, ADDY. In response to the mode signal MS, the control block 500 may output timing control signals to the row selection block 110, the column decoder 120, and the I/O block 400, and may output voltage control signals (VCS) to the voltage generator 600.

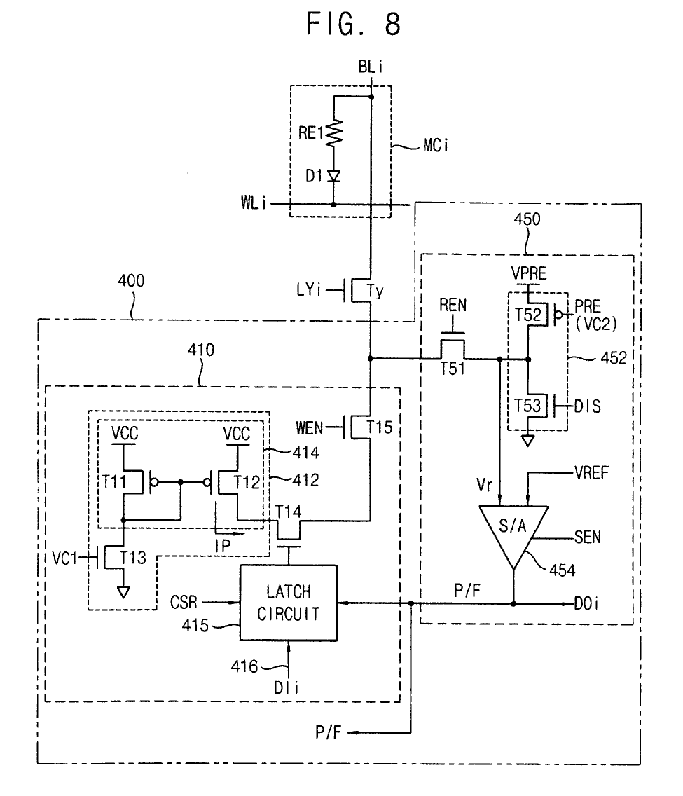

A schematic diagram of the I/O block 400 is illustrated in FIG. 8. The timing control signals may include a write enable signal (WEN), a read enable signal (REN), a sense enable signal (SEN), a precharge signal (PRE), and a discharge signal (DIS). Voltage control signals may includes a supply voltage (VCC), a precharge voltage (VPRE), and first and second voltage signals to the pulse generator 610 configured to generate voltage pulses VC1 and VC2. These voltages are then supplied to the I/O block 400.

The I/O block 400 may include a write driver 410 and a sense amplifier 450. The I/O block 400 may be connected to a memory cell MCi of the memory cell array 10 through a bitline selection transistor Ty, which is controlled by an address signal ADDY, i.e., Lyi. There are numerous such bit line selection transistors Ty in the column decoder 120. The I/O block 400 may be configured for use with a particular design of the memory cells MC, which includes a resistive element RE1 and a diode D1. Details of such a memory cell may be found, for example, in U.S. Pat. No. 7,427,531, which is hereby incorporated by reference in its entirety. A first terminal of the resistive element RE1 may be connected to the bit line BL, a second terminal of the resistive element RE1 may be connected in series with a first terminal of the diode D1, and a second terminal of the diode D1 may be connected to the wordline WL.

The write driver 410 may include transistors T11, T12, T13, T14, T15, and a latch circuit 415. The transistors T11, T12, T13 may form a pulse provider 412 receiving the supply voltage VCC. The transistors T11 and T12 may form a current mirror 412. The transistor T13 may be controlled by the voltage VC1. The latch circuit 415 may receive data to be written through data line 416 Dli and may control the state of the transistor T14 in accordance with the data from the data line 416 and a control signal register (CSR). The transistor T15, coupling the write driver 410 to the bit line selection transistor Ty, is controlled by the write enable signal (WEN).

The sense amplifier 450 may include a precharge circuit 452, including transistors T52 and T53 in series, a comparator 454, and transistor T51. A first terminal of the transistor T52 may receive the precharge voltage VPRE and a second terminal thereof may be connected to a first terminal of the transistor T53. The transistor T52 may be controlled by the precharge signal PRE. The transistor T53 may be controlled by the discharge signal DIS and may have a second terminal thereof connected to ground. The comparator 454 may compare a read voltage Vr with a reference voltage VREF and output the result as pass or fail signal (P/F). The transistor T51, coupling the sense amplifier 450 to the bit line selection transistor Ty, may be controlled by the read enable signal (REN).

During writing of the memory cell MCi, the write enable signal WEN is high, the address signal Lyi is high, and VC1 is high. Therefore, the transistor T13 is turned ON and a current pulse Ip is generated and output from the current mirror 414 through the transistor T15 to the resistance element RE1 of the memory cell MCi. When the control signal register is a low resistance program, e.g., VC1 is Vset, when the data signal is “0”, the transistor T14 is on and, when the data signal is “1”, the transistor 114 is OFF. When the control signal register is a high resistance program, e.g., VC1 is Vreset, when the data signal is “0”, the transistor T14 is ON and, when the data signal is “1”, the transistor T14 is OFF.

During reading of the memory cell MCi, the read enable signal REN is high and the address signal Lyi is high. When the discharge signal DIS is high, the transistor T53 is on and the bitline BLi is coupled to ground. When VC2 is low, transistor T52 is ON and the bitline BLi is coupled to the precharge voltage VPRE. The comparator 454 compares the read voltage Vr and the reference voltage VREF and outputs a data signal. During normal read operation, the data signal is supplied to outside the I/O block 400, i.e., to data output line DOi. During verify read operation, a pass/fail signal P/F is supplied to the latch circuit 415 of the write driver 410 and to the voltage generator 600. When the pass/fail signal is F, VC1 from the pulse generator 610 may be altered, e.g., increased. Thus, the current pulse Ip from the write driver 410 may be altered, e.g., increased. When the pass/fail signal is P, the latch circuit 415 may stop the write operation by turning OFF the transistor T14, regardless of the input data on the data line Dli.

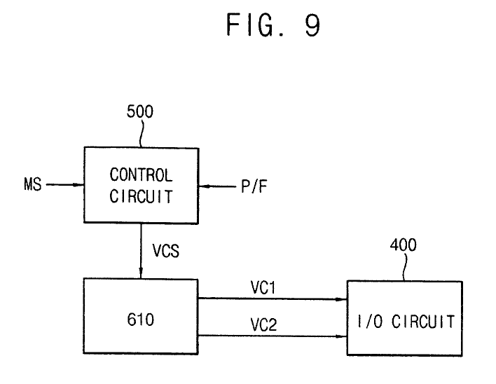

FIG. 9 illustrates a block diagram of the relationship between the control block 500, the pulse generator 610, and the I/O block 400. In particular, the voltage control signal VCS output from the control block 500 in response to the mode signal MS determines which voltage is output to the I/O block 400. For example, when the mode signal MS is low, VC1 may be output from the pulse generator 610 to the I/O block 400 so that programming is performed. When the mode signal MS is high, VC2 may be output from the pulse generator 610 to the I/O block 400 so that verify read or normal read is performed. If the I/O block 400 indicates that not all memory cells for a writeline are properly written, i.e., supplies a fail signal to the control block 500, the voltage control signal VCS may control the pulse generator 610 to alter, e.g., increase, at least one of the magnitude and duration of the pulse VC1.

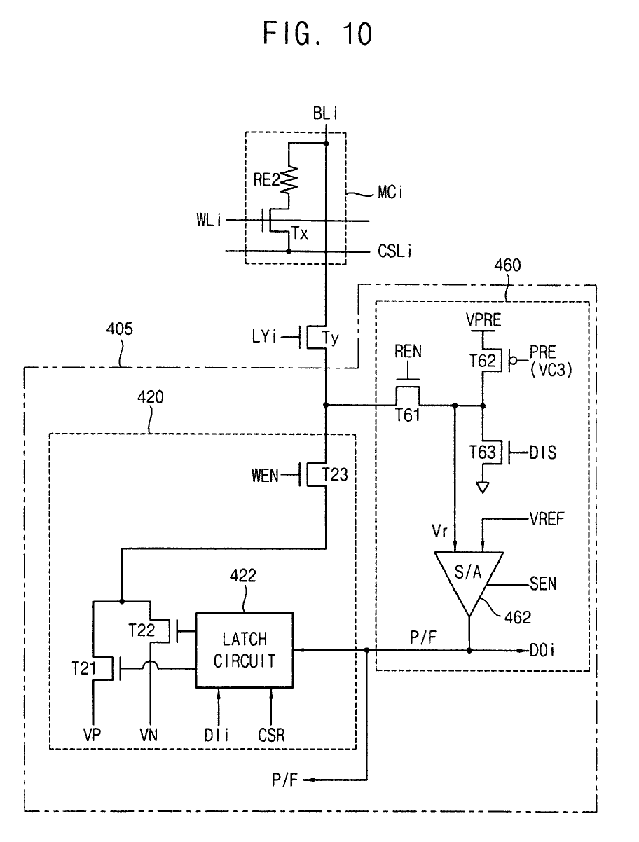

FIG. 10 illustrates schematic diagram of an I/O block 405 in an alternative embodiment. The I/O block 405 may include a write driver 420 and a sense amplifier 460. The I/O block 405 is connected to memory cells MCi′ of the memory cell array 10 through a bitline selection transistor Ty, which is controlled by an address signal ADDY, i.e., Lyi. The I/O block 405 is configured for use with a particular design of the memory cells MC′, which includes a resistive element RE2 and a transistor T1. A first terminal of the resistive element RE2 may be connected to the bit line BL, a second terminal of the resistive element RE1 may be connected in series with a first terminal of the transistor T1, a control terminal of the transistor T1 may be connected to the wordline WL, and a second terminal of the transistor T1 may be connected to a common source line CSL.

The write driver 420 may include transistors T21, T22, T23, and a latch circuit 422. The transistor T21 may receive a positive voltage Vp at the first terminal thereof to program an ON or set state. The transistor T22 may receive a negative voltage Vn at a first terminal thereof to program an OFF or reset state. The latch circuit 422 may control the transistors T21 and T22 in accordance with the data line signal Dli and the control signal register (CSR).

During writing of the memory cell MCi', the write enable signal WEN is high and the address signal Lyi is high. When the control signal register CST is a low resistance program, e.g., Vp is to be used, the latch circuit 422 turns the transistor T22 OFF. When the data signal is “0”, the latch circuit 422 turns the transistor T21 ON and, when the data signal is “1”, the latch circuit 422 turns the transistor T21 OFF. When the control signal register CSR is a high resistance program, e.g., Vn is to be used, the latch circuit 422 turns the transistor T21 OFF. When the data signal is “0”, latch circuit 422 turns the transistor T22 ON and, when the data signal is “1”, latch circuit 422 turns the transistor T22 OFF.

The latch circuit 422 turns the transistor T21 ON and, when the data signal is “1”, the transistor T14 is OFF. When the control signal register CSR is a high resistance program, e.g., VC1 is Vreset, when the data signal is “0”, the transistor T14 is ON and, when the data signal is “1”, the transistor T14 is OFF.

The sense amplifier 460 may include transistors T61, T62, T63, and a comparator 462. The operation of the sense amplifier 460 and the relationship of the elements therein is the same as the sense amplifier 450 of FIG. 8, and details thereof are not repeated.

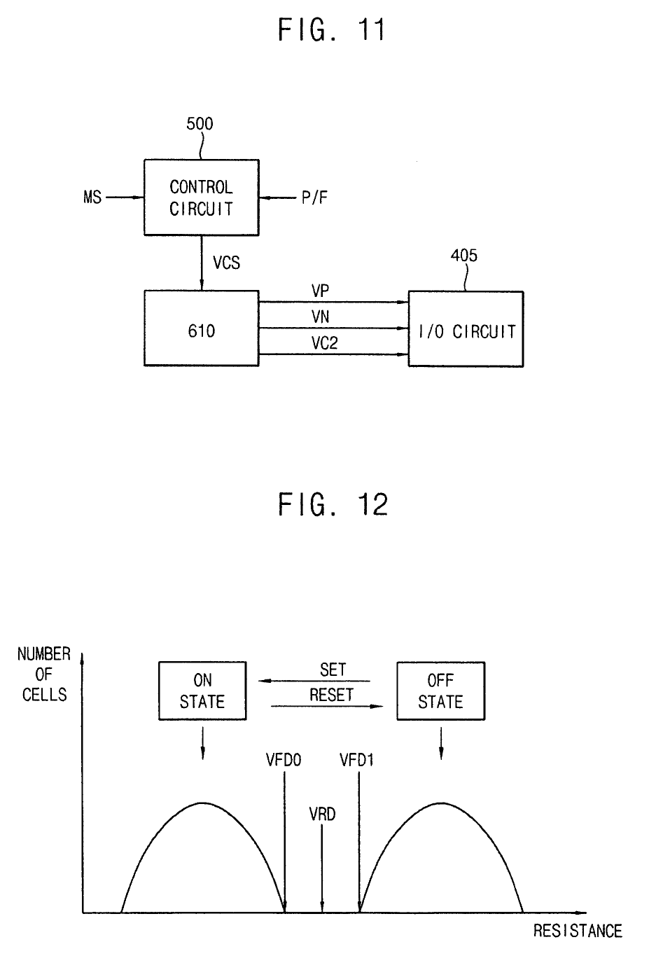

FIG. 11 illustrates a block diagram of the relationship between the control block 500, the pulse generator 610, and the I/O block 405. In particular, the voltage control signal VCS output from the control block 500 in response to the mode signal MS determines which voltage is output to the I/O block 405 from the pulse generator 610. For example, when the mode signal MS is low, the pulse generator 610 may supply Vp and Vn to the I/O block 405 so that programming is performed. When the mode signal MS is high, VC2 may be output from the pulse generator 610 to the I/O block 405 for the precharge so that verify read or normal read is performed

FIG. 12 illustrates a resistance distribution according to an exemplary embodiment. As can be seen in FIG. 12, a reference data voltage VRD may be midway between a highest voltage VRD0 for the resistance distribution for data “0” (set or “ON” state) and a lowest voltage VRD1 for the resistance distribution for data “1” (reset or “OFF” state).

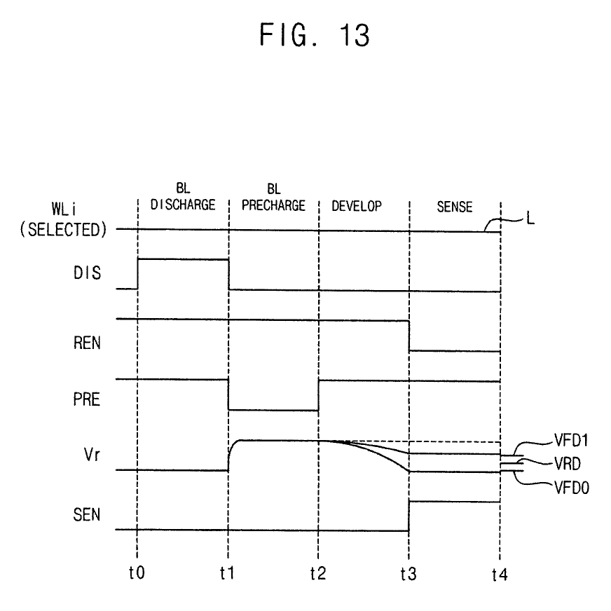

FIG. 13 illustrates a timing diagram for a read operation for use with either sense I/O block 400, 405 in accordance with an embodiment. During a BL discharge period, the discharge signal DIS is high, the read enable signal REN is high, the precharge signal PRE is high, the read voltage Vr is zero, and the sense signal SENS is low. During the BL precharge period, the discharge signal DIS is low, the read enable signal REN is high, the precharge signal PRE is low, the read voltage Vr is precharged to a voltage above any voltage to be programmed, and the sense signal SENS is low. During a develop period, the discharge signal DIS is low, the read enable signal REN is high, the precharge signal PRE is high, the read voltage Vr approaches the voltage stored in the memory cell, and the sense signal SENS is low. During a sense period, the discharge signal DIS is low, the read enable signal REN is low, the precharge signal PRE is high, the read voltage Vr has reached the voltage stored in the memory cell, and the sense signal SENS is high.

If the read voltage is greater than a reference data voltage VRD and data “1” was to be programmed to the memory cell, than the memory cell will pass. If the read voltage is less than a reference data voltage VRD, and data “0” was to be programmed to the memory cell, than the memory cell will pass. Otherwise, the memory cell will fail.

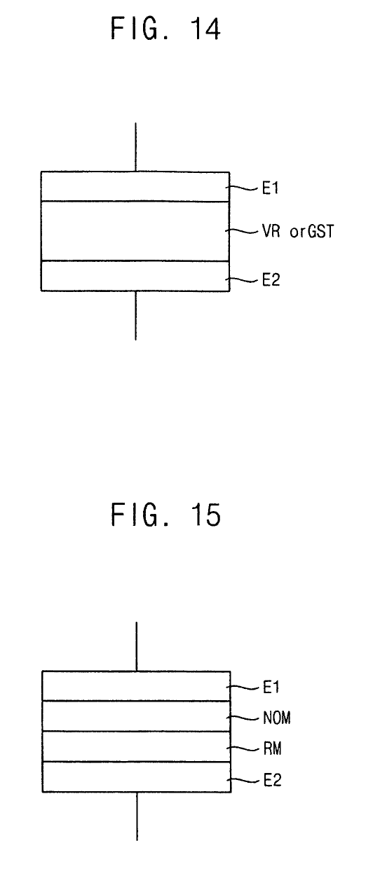

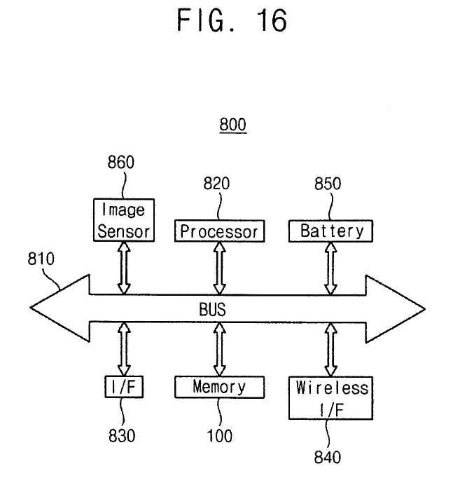

FIGS. 14 and 15 illustrate different types of resistors that may be generally employed with either memory cell configurations illustrated in FIGS. 8 and 10, e.g., a resistor in series with a diode or a transistor. As illustrated in FIG. 14, a resistor may be a unipole resistor including a top electrode E1, a bottom electrode E2, and a negative differential resistive material (NDR) or a chalcogenide material between the top and bottom electrodes. For NDR materials, Rreset>Rset and Vreset<Vset. For other chalocgenide materials, Rreset>Rset and Vreset>Vset. As illustrated in FIG. 15, a resistor may be a bipolar resistor including a nonohmic material NOM, e.g., a metal oxide, and a resistive material RM, e.g., a transition metal oxide, between the top and bottom electrodes E1 and E2. In the bipolar resistor, the memory state is controlled by the polarity of the voltage applied to E1 and E2. In other words, in one memory state, Ve1>Ve2 and in the other Ve1<Ve2.

As noted above, embodiments are not limited to PRAM devices, but may be employed with other resistive memory cells, e.g., RRAM, MRAM, etc. Details of such memory cells may be found, for example, in U.S. Pat. Nos. 6,545,906, 6,646,912, 6,849,891, 7,031,188, and 7,282,756, all of which are hereby incorporated by reference in their entirety.

Further, while the above has focused on the programming of 1-bit data for simplicity, embodiments may be applied to multi-bit data. For example, for storing 2-bit data, the memory cell may be placed in one of four states associated with data values 11, 10, 00, and 01, each of which correspond to unique threshold voltage/resistance distributions. Constituent threshold voltage distributions should be closely controlled to allow each of the threshold voltage distributions to coherently exist within a defined threshold voltage window.

One control method successfully employed to accomplish this goal is a programming method commonly referred to as the incremental step pulse programming (ISPP) scheme as set forth, for example, in co-pending U.S. patent application Ser. No. 12/461,036, filed Jul. 30, 2009, which is hereby incorporated by reference in its entirety. According to the ISPP scheme, a programmed threshold voltage may be moved by defined increments with respect to a given threshold voltage distribution using sequence of program loops. Smaller ISPP programming increments generally allow more accurate definition of a threshold voltage distribution. Careful control of respective threshold voltage distributions allows better voltage margin definitions between data states. However, smaller ISPP programming increments also extend the amount of time required to program a memory cell to a desired state, and longer data programming cycles are generally undesirable. Accordingly, the size of ISPP programming increments must be weighed against programming time. Thus, the reduction in programming time in accordance with embodiments may be particularly useful for programming using ISPP, whether for storing single-bit or multi-bit data.

Alternatively, embodiments may be used with other programming methods as set forth, for example, in U.S. Patent Application Publication Nos. 2008/0123389, which is hereby incorporated by reference in its entirety.

FIG. 16 illustrates a block diagram of a memory system 800 including a semiconductor device according to an exemplary embodiment of the present inventive concept. Referring to FIGS. 1 and 16, the memory system 800, e.g., a computer, may include the memory device 10 and a processor 820 connected to a system bus 110.

The processor 820 may generally control the write operation, the read operation, or the verify read operation of the memory device 100. For example, the processor 820 outputs write data and a command to control the write operation of the memory device 100. Also, the processor 820 may generate a command to control the read operation or the verify read operation of the semiconductor device 10. Thus, the control block (50 in FIG. 6) of the memory device 100 may perform the verify read operation, the program operation, or the write operation in response to the control signal output from the processor 820.

When the memory system 800 is implemented as a portable application, the memory system 800 may further include a battery 850 for supplying operation power to the memory device 100 and the processor 820. The portable application includes portable computers, digital cameras, personal digital assistants (PDAs), cellular telephones, MP3 players, portable multimedia players, automotive navigation systems, memory cards, smart cards, game consoles, electronic dictionaries, or solid state discs.

The memory system 800 may further include an interface I/F 830 for exchange of data with an external data processing device. When the semiconductor system 800 is a wireless system, the memory system 800 may further include a wireless interface I/F 840. In this case, the wireless interface 840 may be connected to the processor 820 to wirelessly exchange data with an external wireless device (not shown) via the system bus 810. For example, the processor 820 may process the data input through the wireless interface 840 and store the processed data in the memory device 100, or read out the data from the memory device 100 and transmit the read data to the wireless interface 840.

The wireless system may be a wireless device such as PDAs, portable computers, wireless telephones, pagers, or digital cameras, radio-frequency identification (RFID) readers, or RFID systems. Also, the wireless system may be wireless local area network (WLAN) systems or wireless personal area network (WPAN) systems. Also, the wireless system may be a cellular network.

When the memory system 800 is an image pick-up device, the memory system 800 may further include an image sensor 860 for converting an optical signal to an electric signal. The image sensor 860 may be an image sensor using a charge coupled device (CCD) or a complementary metal-oxide semiconductor (CMOS) image sensor manufactured using a CMOS process. In this case, the memory system 100 may be a digital camera or a cellular telephone having a digital camera function. Also, the memory system 800 may be an artificial satellite system to which a camera is attached.

Thus, in accordance with embodiments, by simultaneously activating more than one memory cell and/or by determining a pass/fail status on an individual memory cell basis, programming speed of a resistive memory device may be increased.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A memory device, comprising:
an array of resistance change memory cells divided into a first memory block including a first selected memory cell of a first plurality of memory cells and a second memory block including a second selected memory cell of a second plurality of memory cells; and
sensing and writing circuitry configured to simultaneously activate a line connected with the first and second selected memory cells, to write the first and second selected memory cells with write data by applying a level-controlled write signal to the first and second selected memory cells, to perform a verify-read operation on the first and second selected memory cells, and, when at least one of the first and second selected memory cells has a programmed state that is not equal to the write data, to iteratively apply the level-controlled write signal to the at least one of the first and second selected memory cells not having a programmed state equal to the write data until the verify-read operation indicates respective programmed states for the first and second selected memory cells are equal to the write data.

2. The memory device as claimed in claim 1, wherein, to iteratively apply the level-controlled write signal, the sensing and writing circuitry is configured to iteratively alter at least one of a magnitude, a width, and a slope of the level-controlled write signal.

3. The memory device as claimed in claim 2, wherein the sensing and writing circuitry is configured to iteratively increase at least one of a magnitude, a width, and a slope of the level-controlled write signal.

4. The memory device as claimed in claim 1, wherein a plurality of blocks form a tile, adjacent tiles sharing sensing and writing circuitry.

5. The memory device as claimed in claim 1, wherein the sensing and writing circuitry is configured to iteratively apply the level-controlled write signal to a third selected memory cell of a third plurality of memory cells not having a programmed state equal to the write data.

6. The memory device as claimed in claim 5, wherein the third selected memory cell is in a same block as one of the first and second memory blocks having a memory cell having a programmed state equal to the write data and the sensing and writing circuitry is configured to simultaneously activate a line connected with the third selected memory cell and one of the first and second memory blocks having a memory cell not having a programmed state equal to the write data.

7. The memory device as claimed in claim 5, wherein the third selected memory cell is in a different block than either one of the first and second memory blocks and the sensing and writing circuitry is configured to simultaneously activate a line connected with the first to third selected memory cells.

8. The memory device as claimed in claim 7, wherein one of the first and second memory blocks has a memory cell having a programmed state equal to the write data and the sensing and writing circuitry is configured to simultaneously activate a line connected with the third selected memory cell and one of the first and second memory blocks having a memory cell not having a programmed state equal to the write data.

9. The memory device as claimed in claim 1, wherein, in each iteration, the sensing and writing circuitry is configured to use an available voltage amount for each simultaneous activation of lines.

10. The memory device as claimed in claim 1, wherein the resistance change memory cell is a phase change memory cell.

11. The memory device as claimed in claim 10, wherein phase change memory cell includes a diode.

12. The memory device as claimed in claim 1, wherein the sensing and writing circuitry is configured to verify read more memory cells simultaneously than were activated simultaneously.

13. The memory device as claimed in claim 1, wherein the write data is programmed as multi-level state in the memory cell.

14. A method of writing data in a phase change memory cell in a memory, the memory including N tiles, where N is greater than 2, the method comprising:
activating M memory cells, where M is greater than 2, in N tiles simultaneously, one memory cell within a tile be activated at a time;
simultaneously supplying a write signal to the M memory cells in the N tiles;
verify-reading the M memory cells in N tiles simultaneously; and
when Q memory cells in N tiles pass, supplying the write signal to the M-Q memory cells in the N-Q tiles, wherein an amplitude of the write signal supplied to the M memory cells is less than the product of M and an amplitude of a single cell write signal.

15. The method as claimed in claim 14, wherein supplying the write signal includes sequentially programming each memory cell in individual ones of the N tiles.

16. The method as claimed in claim 14, wherein the memory includes partitions of P tiles.

17. The method as claimed in claim 16, wherein each tile within a partition has a selected memory cell.

18. The method as claimed in claim 16, wherein the partition includes two planes of P/2 tiles, the two planes being physically separated.

19. The method as claimed in claim 16, wherein adjacent planes of different partitions share a sensing and writing circuit.

20. The method as claimed in claim 14, wherein, in each iteration, supplying the write signal uses an available voltage amount for each simultaneous supplying of write signals.

21. The method as claimed in claim 14, wherein supplying the write signal to the M-Q memory cells in the N-Q tiles includes altering at least one of a magnitude, a width, and a slope of the write signal.

22. A system, comprising:
a processor; and
a memory device, including
an array of resistance change memory cells divided into a first memory block including a first selected memory cell of a first plurality of memory cells and a second memory block including a second selected memory cell of a second plurality of memory cells, and
sensing and writing circuitry configured to simultaneously activate a line connected with the first and second selected memory cells, to write the first and second selected memory cells with write data by applying a level-controlled write signal to the first and second selected memory cells, to perform a verify-read operation on the first and second selected memory cells, and, when at least one of the first and second selected memory cells has a programmed state that is not equal to the write data, to iteratively apply the level-controlled write signal to the at least one of the first and second selected memory cells not having a programmed state equal to the write data until the verify-read operation indicates respective programmed states for the first and second selected memory cells are equal to the write data.
